(19) United States
(12) Patent Application Publication
(10) Pub. No.: US 2006/0028798 A1
(43) Pub. Date: Feb. 9, 2006

(54) Heat-radiating device assembly

(76) Inventor: Jun-Qian Wang, Shen Yang City (CN)

Correspondence Address: MOLEX INCORPORATED, 2222 WELLINGTON COURT, LISLE, IL, 60532, US

(21) Appl. No.: 11/199,114

(22) Filed: Aug. 8, 2005

(30) Foreign Application Priority Data
Aug. 6, 2004 (CN) 200420084863.3

(51) Int. Cl. H05K 7/20

(52) U.S. Cl. 361/697; 361/700; 165/80.3; 165/125

(57) ABSTRACT

A heat-radiating device assembly includes at least a radiator including a base, a plurality of radiating fins, and two heat pipes. The radiating fins are aligned in parallel on the top surface of the base and two opposite and large area radiating surfaces are provided thereon, each of the upper side of the radiating surfaces is provided with two through holes. The two heat pipes are connected and mounted between the through holes of the radiating fins and the base, the lower surface of the base is attached with the top surface of an electronic element to radiate heat therefrom, wherein one lateral edge of the radiating surfaces of the radiating fins is generally arc shaped, V-shaped in the disclosed embodiment, with two raised outward upper and lower ends and a depressed inward center. With the structure of the radiating fins shown in the present invention, the windage of the radiator is reduced and the amount of air flow is increased, and thus the reduced noise and the improved heat dissipating effects are obtained. In addition, the radiating fin structure used in the present invention reduces the material used to make the radiating fins thereby reducing the weight.

### FIELD OF THE INVENTION

The present invention relates to a heat-radiating device assembly, and in particular, to a heat-radiating device assembly with low noise and good heat dissipating properties.

### BACKGROUND OF THE INVENTION

With the developments in the microprocessor industry that has allowed for reduced size and more complex integrated circuits, the heat produced by their electronic devices in operation increases sharply so that the temperature of the devices rises to affect the normal operation of the devices. Herein, the temperature of the CPU is very high in operation. Thus, it needs to provide a heat dissipation device to ensure the normal operation of the CPU in a proper temperature range.

The conventional heat-radiating device is often composed of a radiator and a fan, the radiator includes a base and a plurality of radiating fins mounted on the top surface of the base, and the base of the radiator is mounted on the top surface of the CPU to dissipate heat.

In recent years, in order to improve the radiating efficiency of the radiator, a typical technique is applying a heat pipe in the radiator to obtain a better heat dissipating effect by using the heat conductivity of the heat pipe. For example, Taiwan patent No. 091208843 discloses a combined structure of radiating fins and heat pipes in which through holes are provided on the upper side of the rectangular sheet shaped radiating fins and two heat pipes are connected and mounted between the radiating fins and the base. However, the heat flow conducts heat upward from the bottom of the base, and the heat pipes have a very high conductivity, thus temperatures of the bottom of the radiating fins at the location of the base and the top of radiating fins connected with the heat pipes are higher and that of the middle of the radiating fins is lower so that the air flow passing through the middle of the radiating fins can take away less heat and the radiating efficiency is lower. On the other hand, the width in the middle of the radiating fins is the same with that in the top and the bottom of the radiating fins so that the airflow of the radiating fins is stronger, the noise is increased and the amount of the airflow is reduced. Thus, there are improvements that can be made to the prior heat radiating device assembly to overcome the shortcomings identified above.

### SUMMARY OF THE INVENTION

A major object of the present invention is to provide a heat-radiating device assembly, especially to a heat-radiating device assembly with low noise and good heat dissipating properties.

To achieve the above object, the present utility model provides the following technical solution:

a heat-radiating device assembly includes a radiator, a radiating fan, a fan fixing frame and two fixing structures, the radiator includes a base, a plurality of radiating fins, and two heat pipes, the radiating fins are aligned in parallel on one side of the base and two opposite and large area radiating surfaces are provided thereon, the radiating surfaces have two pairs of opposite lateral edges, one of the first lateral edge pair is coupled to one side of the base and two through holes are provided in a proper position close to the other lateral edge of the first lateral edge pair. The two heat pipes are connected and mounted between the through holes of the radiating fins and the base, the opposite side of the base is attached to the surface of a CPU for radiating heat for the CPU. One lateral edge of the second lateral edge pair of the radiating surfaces of the radiating fins has a generally arc shaped cutout (in this specific embodiment it is generally “V” shaped) with two raised outward upper and lower ends and a depressed inward center, and the other one of the second lateral edge pair is formed into a straight line, the radiating fan is mounted on the same side with the straight line lateral edge of the radiating fins, the cooling air flow is fed from the side of the generally V-shaped lateral edge of the radiating fins and is drawn and vented out of the radiator by the radiating fan after flowing through the radiating fins.

The heat-radiating device assembly according to the present invention and the prior heat-radiating device assembly having the prior radiating surfaces of the radiating fins are tested and contrasted when the thermal power of the CPU is 109 watt, the noise value is reduced from 40 dB to 36 dB and the surface temperature of the CPU is reduced from 66.9 degree to 64.9 degree. Known from the test result, the heat-radiating device assembly according to the present invention has reduced noise and more effective in dissipating heat due to the change in the shape of the radiating fins.

In addition, the structure of the radiating fins of the heat-radiating device assembly according to the present invention also reduces the amount of material used for the radiating fins, thereby reducing the weight of radiator.

### BRIEF DESCRIPTION OF THE DRAWINGS

The organization and manner of the structure and operation of the invention, together with further objects and advantages thereof, may best be understood by reference to the following description taken in connection with the accompanying drawings wherein like reference numerals identify like elements in which:

FIG. 1 is an isometric combined view of the heat-radiating device assembly according to the utility model;

FIG. 2 is an isometric combined view from another aspect of the heat-radiating device assembly according to the utility model;

FIG. 3 is a front view of the heat-radiating device assembly according to the utility model;

FIG. 4 is an isometric exploded view of the heat-radiating device assembly according to the utility model.

### DETAILED DESCRIPTION OF THE DISCLOSED EMBODIMENT

While this invention may be susceptible to embodiment in different forms, there is shown in the drawings and will be described herein in detail, a specific embodiment with the understanding that the present disclosure is to be considered an exemplification of the principles of the invention, and is not intended to limit the invention to that as illustrated.

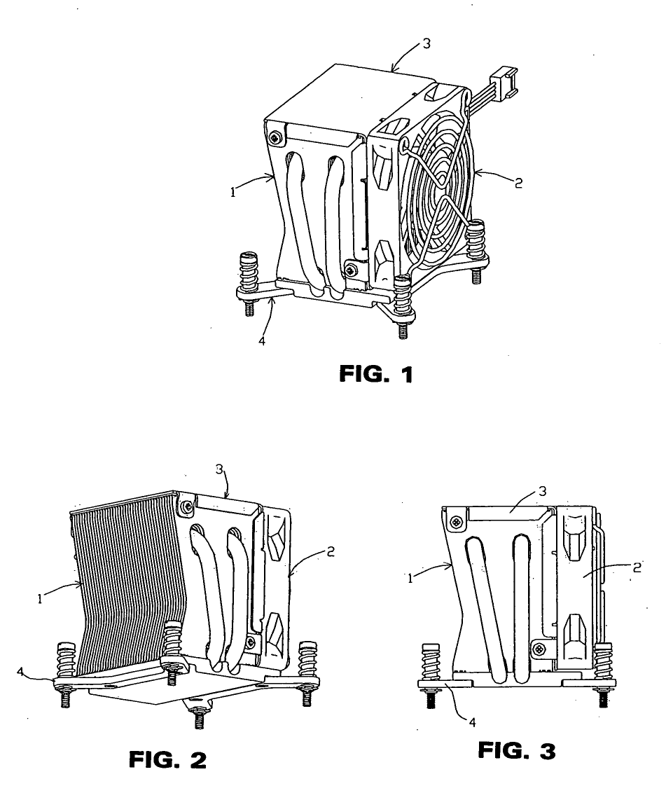

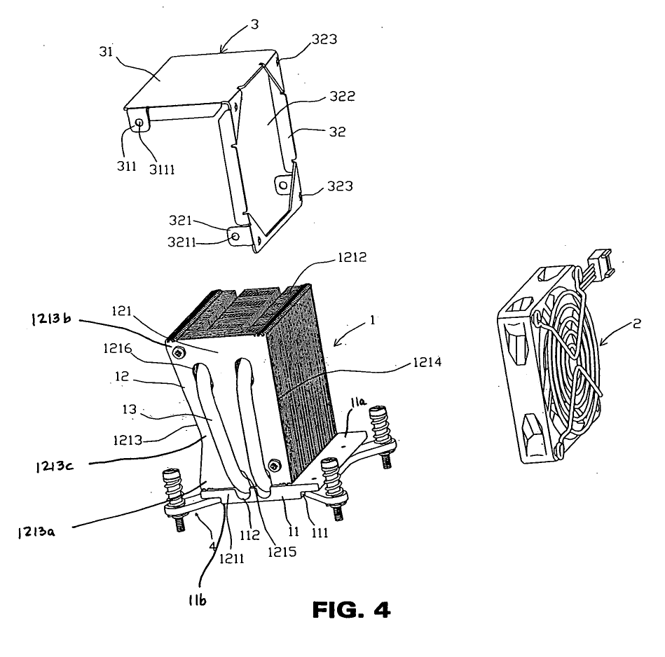

Referring to FIG. 1 to FIG.4, the heat-radiating device assembly according to the utility model can be mounted to a circuit board (not shown) and be attached to the top surface of a CPU for dissipating heat from the CPU so as to ensure its steady operation within its operating temperature range.

The heat-radiating device assembly mainly includes a radiator 1, a radiating fan 2, a fan fixing frame 3, and two fixing structures 4.

The radiator 1 includes a base 11, a plurality of radiating fins 12 mounted in parallel on the top surface 11a of the base 11, and two heat pipes 13 bent into a generally U shape. The radiating fins 12 may be formed separately by forge press and then be soldered to the top surface of the base 11. Alternatively, it may also be formed integrally by cast with the base 11. Each of two sides of the bottom surface of the base 11 is provided with a depressed portion as a fixing portion 111, and the middle of the top surface of the base 11 is provided with two grooves 112. The radiating fins 12 have two opposite and large area radiating surfaces 121 which have two pairs of opposite lateral edges 1211,1212,1213,1214. The lower lateral edges 1211 of the first lateral edge pair 1211,1212 are coupled to the top surface of the base 11, where faces correctly to the grooves 112 is provided with two half-arc shape groove 1215 and a proper position close to the upper lateral edge 1212 of the first lateral edge pair is provided with two through holes 1216. One lateral edge 1213 of the second lateral edge pair of the radiating surface 121 of the radiating fins 12 is designed with a generally arc shaped cutout. In this particular embodiment, the arc shaped cutout is generally “V” shaped with two raised outward upper ends 1213b and two raised outward lower 1213a ends and a depressed inward center 1213c and the other lateral edge 1214 is formed into a straight line. One end of each of the two heat pipes 13 is penetrated and soldered into the through holes 1216 of the radiating fins 12 and the other end is penetrated and soldered into the groove 112 of the base 11 so as to conduct effectively the heat from the base 11 to the upper side of the radiating fins 12, and thus the radiating efficiency of the radiator 1 is improved.

The fan-fixing frame 3 is L-shaped and is fixed to the top surface of the radiating fins 12 and the other lateral edge 1214. The fan fixing frame 3 mainly includes an upper stopping plate 31 which covers over the radiating fins 12 to limit the flow direction of the cooling air flow and bends vertically toward its two sides in its ends to extend into a fixing tab 311 on which provides a bolt hole 3111, and a fan fixing portion 32 which has a frame structure, in the middle of which provides a large area vent hole 322, in each of four corners of which provides a bolt hole 323, and in the end of which bends vertically toward its two sides to extend into a fixing tab 321 on which provides a bolt hole 3211. Since bolts pass through the bolt hole 3111 and 3211 and are fastened to the radiating fins 12, the fan fixing frame 3 is fixed to the radiator 1.

The radiating fan 2 is an axial flow fan which can improve the radiating efficiency of the radiator 1 by accelerating the flowing of the air flow. In each of four corners of the radiating fan 2 provides a lock hole to fasten the radiating fan 2 to the fan fixing frame 3 by passing bolts through the lock hole and bolting them into the bolt hole 323 of the fan fixing frame 3. In this embodiment, the radiating fan 2 is an air draft fan, the cooling air flow is fed from the side of the generally V-shaped lateral edge 1213 of the radiating fins, flows through the radiating surface 121 of the radiating fins 12, flows out of the lateral edge 1214, and then is drawn and vented out of the radiator 1 by the radiating fan 2. Two fixing structures 4 are bolted to the fixing portion 111 of the base 11 of the radiator 1 by bolts, respectively, thus the radiator 1 can be fixed to a circuit board (not shown) and the bottom surface 11b of the base 11 can be attached with the top surface of a CPU (not shown).

The heat-radiating device assembly has the following characters in that: the lateral edge 1213 of the radiating surface 121 of the radiating fins 12 is a generally V shape with two raised outward upper and lower ends and a depressed inward center. Compared with the typical rectangular radiating fins with four straight line shaped lateral edges, for this radiator 1, the width and the area in the middle of the radiating fins 12 with lower radiating efficiency are reduced, the whole windage of the radiating fins 12 is reduced and the amount of air flow is increased, and thus the distribution of air flow of the radiator 1 is improved. As known from the general common knowledge, the present invention may be implemented by other embodiments without departing from its spirit and essential features. For example, the number of the heat pipe 13 may be one, three etc.; also, the radiating fan 2 may be a blowing fan to flow the air flow in the direction opposite to that in this embodiment, while the lateral edge 1214 is a V shape with two raised outward upper and lower ends and a depressed inward center and the lateral edge 1213 is a straight line as normally used, other reduced surface area shaped fins can be used to obtain a like effect. Thus, while a preferred embodiment of the invention is shown and described it is envisioned that those skilled in the art may devise various modifications without departing from the spirit and scope of the foregoing description and the appended claims.

What is claimed is:

1. A heat-radiating device assembly including at least a radiator, wherein the radiator includes a base, a plurality of radiating fins, and at least one heat pipe, the radiating fins are aligned in parallel on one side of the base and two opposite and large area radiating surfaces having two pair of opposite lateral edges are provided thereon, one lateral edge of the first lateral edge pair is coupled to one side of the base and at least one through hole is provided in a proper position close to the other one of the first lateral edge pair; the at least one heat pipe is connected and mounted between the through holes of the radiating fins and the base, wherein at least one lateral edge of the second lateral edge pair of the radiating surfaces of the radiating fins has a generally arc shaped reduced surface area location defined by two raised outward ends and a depressed inward center.

2. The heat-radiating device assembly according to claim 1, wherein the arc shaped reduced surface area location is generally V shaped.

3. The heat-radiating device assembly according to claim 1, wherein the radiating fins are formed separately by press forging and then are soldered to one side of the base.

4. The heat-radiating device assembly according to claim 1, wherein the radiating fins are formed integrally by casting with the base.

5. The heat-radiating device assembly according to claim 1, wherein the heat pipe is bent to be U-shaped, one side of the base provides a plurality of grooves, one end of the heat pipe penetrates into the through hole of the radiating fins, and the other end penetrates into the groove of the base.

6. The heat-radiating device assembly according to claim 1, wherein one lateral edge of the second lateral edge pair of the radiating surfaces of the radiating fins has two raised outward ends and a depressed inward center, and the other one lateral edge of the second lateral edge pair of the radiating surfaces of the radiating fins is a straight line.

7. The heat-radiating device assembly according to claim 6, wherein the heat-radiating device assembly further includes a radiating fan mounted on the same side with the straight line shaped lateral edge of the radiating fins, the radiating fan having a cooling air flow fed from the side of the generally arc shaped reduced surface area location of the radiating fins and flows out of the side of straight line shaped lateral edge after flowing through the radiating fins, and then is drawn and vented out of the radiator by the radiating fan.

8. The heat-radiating device assembly according to claim 7, wherein the heat-radiating device assembly further includes a fan fixing frame which is fastened to the same side with the straight line shaped lateral edge of the radiating fins, the radiating fan is fixed and mounted to the fan fixing frame.

9. The heat-radiating device assembly according to claim 1, wherein the heat-radiating device assembly further includes a radiating fan mounted to the same side as the generally arc shaped reduced surface area location of the radiating fins.

10. The heat-radiating device assembly according to claim 1, wherein the other side opposite to the base of the radiator is attached tightly to the top surface of an electronic element for helping radiating heat therefrom to ensure the normal operation of the electronic element.

11. The heat-radiating device assembly according to claim 2, wherein the radiating fins are formed separately by press forging and then are soldered to one side of the base.

12. The heat-radiating device assembly according to claim 2, wherein the radiating fins are formed integrally by casting with the base.

13. The heat-radiating device assembly according to claim 2, wherein the heat pipe is bent to be U-shaped, one side of the base provides a plurality of grooves, one end of the heat pipe penetrates into the through hole of the radiating fins, and the other end penetrates into the groove of the base.

14. The heat-radiating device assembly according to claim 2, wherein one lateral edge of the second lateral edge pair of the radiating surfaces of the radiating fins is V-shaped with two raised outward ends and a depressed inward center, and the other one lateral edge of the second lateral edge pair of the radiating surfaces of the radiating fins is a straight line.

15. The heat-radiating device assembly according to claim 14, wherein the heat-radiating device assembly further includes a radiating fan mounted on the same side with the straight line shaped lateral edge of the radiating fins, the radiating fan having a cooling air flow fed from the side of the V-shaped lateral edge of the radiating fins and flows out of the side of straight line shaped lateral edge after flowing through the radiating fins, and then is drawn and vented out of the radiator by the radiating fan.

16. The heat-radiating device assembly according to claim 15, wherein the heat-radiating device assembly further includes a fan fixing frame which is fastened to the same side with the straight line shaped lateral edge of the radiating fins, the radiating fan is fixed and mounted to the fan fixing frame.

17. The heat-radiating device assembly according to claim 2, wherein the heat-radiating device assembly further includes a radiating fan which is mounted to the same side as the V-shaped lateral edge of the radiating fins.

18. The heat-radiating device assembly according to claim 2, wherein the other side opposite to the base of the radiator is attached tightly to the top surface of an electronic element for helping radiating heat therefrom to ensure the normal operation of the electronic element.
